(19) United States
(12) Patent Application Publication
(10) Pub. No.: US 2019/0348621 A1
(43) Pub. Date: Nov. 14, 2019

(54) OPTOELECTRONIC FOIL AND MANUFACTURING METHOD OF OPTOELECTRONIC FOIL

(71) Applicant: SAULE SP. Z.O.O., Warszawa (PL)

(72) Inventors: Konrad WOJCIECHOWSKI, Wroclaw (PL); Olga Malinkiewicz, Warszawa (PL); Bartosz Bursa, Nowy Tomysl (PL); Juan Pablo Prieto Ruiz, Paterna Valencia (ES); Barbara Wilk, Wroclaw (PL); Artur Kupczunas, Kalisz (PL)

(21) Appl. No.: 16/521,645

(22) Filed: Jul. 25, 2019

Related U.S. Application Data
(63) Continuation-in-part of application No. PCT/PL2018/000008, filed on Jan. 24, 2018.

(30) Foreign Application Priority Data
Jan. 25, 2017 (PL) P.420300

(51) Int. Cl. H01L 51/00; G02F 1/1333; C23C 14/35; C23C 14/08; C23C 14/20; C23C 14/02

(52) U.S. Cl. CPC H01L 51/0097; G02F 1/133305; C23C 14/022; C23C 14/086; C23C 14/205; C23C 14/35

(57) ABSTRACT

An optoelectronic foil comprising a substrate and a conductive layer comprising at least one oxide layer and at least one metal layer, wherein between the conductive layer and the substrate of the foil there is a barrier layer comprising at least one material selected from the group consisting of silicon oxides (SiOₓ), aluminium oxides (Al₂O₃, AlOₓN_{y}), titanium oxides (TiOₓ), silicon oxynitrides SiON, silicon nitrides (Si₃N₄, SiNₓ), organic silicon compounds (SiCₓH_{y}), zirconium oxide (ZrO₂), hafnium oxide (HfO₂), chromium oxides (CrO, Cr₂O₃, CrO₂, CrO₃, CrO₅) and parylene.

### FIELD AND BACKGROUND OF THE INVENTION

The invention relates to an optoelectronic foil and a method for the production thereof.

In terms of design, the optoelectronic foil consists of a flexible polymer foil substrate and a transparent electrode. It is the basis for the construction of a wide array of optoelectronic devices that are produced on said foils using a variety of techniques. Optoelectronic devices, for the construction of which optoelectronic foils are used, include flexible emission displays (OLED, QD LCD), flexible photovoltaic devices, touch screen sensors, flexible random access memory (RAM) and gas sensors.

The disadvantage of optoelectronic flexible foils lies in the poor tightness of the flexible substrate constituted by polymer foils with a high oxygen and water permeability coefficient, which result in the short lifespan of optoelectronic devices. Especially devices containing organic materials in active layers, for example OLEDs (Organic Light Emitting Diodes) are sensitive to weather conditions. Moisture and oxygen penetration from the air cause the degradation of the active material, which, as a result, precludes the optoelectronic device from operating.

Various technologies are known for the production of protective layers in the structure of optoelectronic foils designed to extend the lifespan of optoelectronic devices, including the “Dam-and-fill” encapsulation technique. During this process, a high viscosity fluid is distributed, forming a rectangular barrier around the device (e.g. an OLED). Said fluid is distributed during the droplet application process so as to fill the space between the substrate and the barrier film within the barrier.

### SUMMARY OF THE INVENTION

The invention relates to an optoelectronic foil that comprises a substrate and a conductive layer comprising at least one oxide layer and at least one metal layer, wherein between the conductive layer and the substrate of the foil there is a barrier layer comprising at least one material selected from the group consisting of silicon oxides (SiOₓ), aluminium oxides (Al₂O₃, AlOₓN_{y}), titanium oxides (TiOₓ), silicon oxynitrides SiON, silicon nitrides (Si₃N₄, SiNₓ), organic silicon compounds (SiCₓH_{y}), zirconium oxide (ZrO₂), hafnium oxide (HfO₂), chromium oxides (CrO, Cr₂O₃, CrO₂, CrO₃, CrO₅) and parylene.

In certain embodiments, the barrier layer is a monolayer structure.

In certain embodiments, the barrier layer is a multi-layer structure consisting of at least two sublayers stacked one on the other within the barrier layer and made of different material.

In certain embodiments, the substrate is made of at least one plastic selected from the group consisting of: polyethylene terephthalate (PET), polyethylene naphthalene (PEN), polyethylene (PE), polypropylene (PP), polyethersulfone (PES), polyimide (PI), polystyrene (PS), ethylene/tetrafluoroethylene (ETFE) and parylene.

In certain embodiments, inorganic nanocomposites are admixed to the substrate.

In certain embodiments, the oxide layer is made of at least one oxide selected from the group consisting of: ZnO, AZO (aluminium zinc oxide), SnO₂, IZO (indium zinc oxide), FTO (fluorine tin oxide), ZTO (tin zinc oxide), ITO (tin indium oxide), GZO (zinc gallium oxide), GIO (indium gallium oxide), In₂O₃, Sb:SnO₂, IO:H (hydrogen indium oxide), CdO, Zn₂SnO₄, ZnSnO₃, Zn₂In₂O₅, NiOₓ, NiOₓ:Li, TiOₓ, ZnS, ZnSe, Te₂O₃, MoOₓ, V₂O₅ and WO₃.

In certain embodiments, the oxide layer is a monolayer structure.

In certain embodiments, the oxide layer is a multi-layer structure consisting of at least two sublayers stacked one on the other within the oxide layer and made of different material.

In certain embodiments, the foil comprises one oxide layer.

In certain embodiments, the foil comprises at least two oxide layers.

In certain embodiments, the metal layer is made of at least one material selected from the group consisting of: Al, Ti, Ni, Cr, Au, Mg, Ta, Ge, Ag, Cu, Zr, Pt and W.

In certain embodiments, the foil has a metal layer between adjacent oxide layers.

In certain embodiments, within the conductive layer, the foil has n oxide layers and n−1 metal layers arranged alternately between adjacent oxide layers.

The invention further relates to a method of manufacturing an optoelectronic foil characterised in that a selected surface of the substrate is cleaned and activated onto which a barrier layer is deposited so as to form a barrier layer on said cleaned and activated substrate that comprises at least one material selected from the group consisting of silicon oxides (SiOx), aluminium oxides (Al₂O₃, AlOₓN_{y}), titanium oxides (TiOₓ), silicon oxynitrides SiON, silicon nitrides (Si₃N₄, SiNₓ), organic silicon compounds (SiCₓH_{y}), zirconium oxide (ZrO₂), hafnium oxide (HfO₂), chromium oxides (CrO, Cr₂O₃, CrO₂, CrO₃, CrO₅) and parylene, and then a conductive layer comprising at least one oxide layer and at least one metal layer is deposited onto the barrier layer.

In certain embodiments, the barrier layer is formed by depositing one layer of material onto the substrate to form a barrier layer having a monolayer structure.

In certain embodiments, the barrier layer is formed by depositing at least two sublayers of different material onto the substrate to form a barrier layer having a multi-layer structure.

In certain embodiments, the conductive layer is formed so that at least one oxide layer is individually formed one on another on the barrier layer made of an oxide material comprising at least one oxide selected from the group consisting of: ZnO, AZO (aluminum zinc oxide), SnO₂, IZO (indium zinc oxide), FTO (fluorine tin oxide), ZTO (tin zinc oxide), ITO (tin indium oxide), GZO (zinc gallium oxide), GIO (indium gallium oxide), In₂O₃, Sb:SnO₂, IO:H (hydrogen indium oxide), CdO, Zn₂SnO₄, ZnSnO₃, Zn₂In₂O₅, NiOₓ, NiOₓ:Li, TiOₓ, ZnS, ZnSe, Te₂O₃, MoOₓ, V₂O₅ and WO₃ and at least one metal layer of a material comprising at least one metal selected from the group consisting of: Al, Ti, Ni, Cr, Au, Mg, Ta, Ge, Ag, Cu, Zr, Pt and W.

In certain embodiments, the conductive layer is formed so that on the barrier layer there are individually formed one on another, with the alternating arrangement of oxide layers and metal layers, n oxide layers and n−1 metal layers, where n is a natural number.

In certain embodiments, the conductive layer is formed so that on the barrier layer there are individually formed a first oxide layer, then a metal layer is formed on the first oxide layer, and then a second oxide layer is formed on the metal layer.

In certain embodiments, at least one oxide layer is formed by depositing one layer of oxide material to form an oxide layer having a monolayer structure.

In certain embodiments, at least one oxide layer is formed by depositing at least two oxide sublayers of different material to form an oxide layer having a multi-layer structure.

In certain embodiments, the substrate is cleaned and activated using at least one technique selected from the group consisting of: plasma treatment, corona discharge treatment, carbon dioxide treatment, ultraviolet radiation and ozone treatment, and cleaning with solvents selected from the group consisting of acetone, isopropanol, water, mixture of acetone with water and mixture of isopropanol and water.

In certain embodiments, the barrier layer is deposited onto the substrate using at least one technique selected from the group consisting of atomic layer deposition (ALD), magnetron sputtering, electron-beam sputtering technique and thermal evaporation technique.

In certain embodiments, the conductive layer is deposited onto the substrate using at least one technique selected from the group consisting of atomic layer deposition (ALD), magnetron sputtering, electron-beam sputtering technique and thermal evaporation technique.

These and other features, aspects and advantages of the invention will become better understood with reference to the following drawings, descriptions and claims.

### BRIEF DESCRIPTION OF THE DRAWINGS

Various embodiments are herein described, by way of example only, with reference to the accompanying drawings, wherein:

FIG. 1 schematically shows a cross-section of the structure of an optoelectronic foil according to one embodiment of the invention;

FIG. 2 shows a flowchart of the optoelectronic foil manufacturing process, in accordance with an embodiment of the invention; and

FIG. 3 schematically shows a cross-section of the structure of an optoelectronic foil according to another embodiment of the invention.

### DETAILED DESCRIPTION OF THE INVENTION

The following detailed description is of the best currently contemplated modes of carrying out the invention. The description is not to be taken in a limiting sense, but is made merely for the purpose of illustrating the general principles of the invention, since the scope of the invention is best defined by the appended claims.

The optoelectronic foil according to the invention has a transparency of no less than 50% and is characterised by low water vapor permeability, as the water vapor transmission rate (WVTR) of the optoelectronic foil 10 is between 10⁻³ and 10⁻⁶ g/m² per day. Due to optoelectronic properties and high transparency, the foil can be used for the manufacture of various devices, including, but not limited to, devices from the field of imaging optoelectronics and photovoltaic optoelectronics. For example, the foil can be used for the manufacture of flexible OLED or QD LCD displays, in photovoltaic systems, including, but not limited to, ultra-thin, transparent photovoltaic cells that can be placed on window panes, computer screens, mobile phones, clothing parts, and other everyday use items. Due to improved barrier properties and improved lifespan, the foil can also be used in the automotive or construction industry.

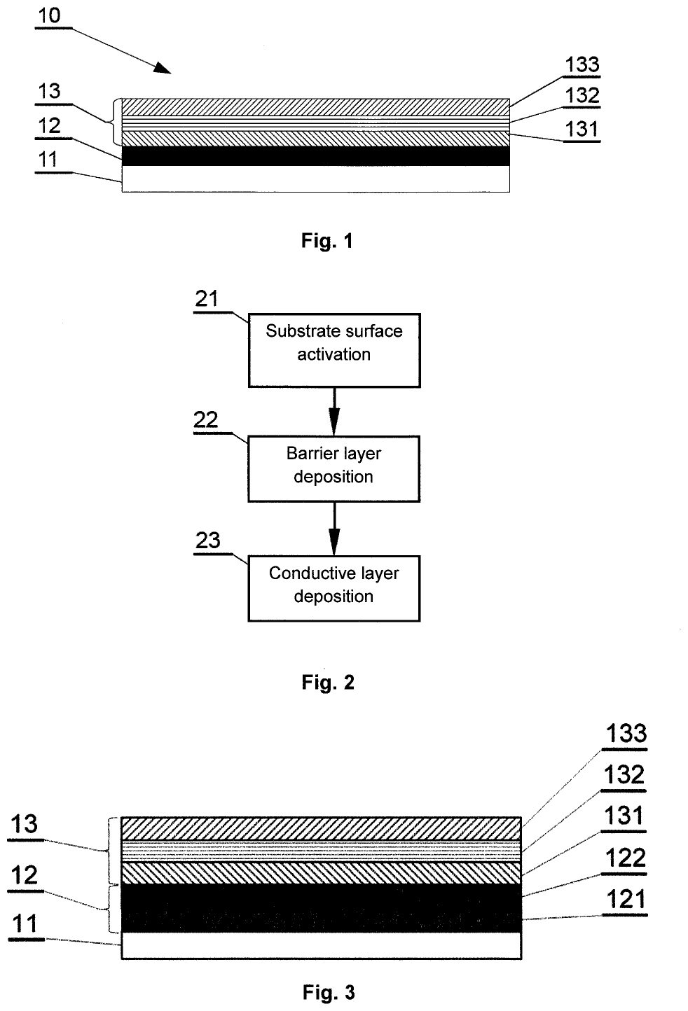

FIG. 1 schematically illustrates the optoelectronic foil in a cross-section, showing the layered foil construction. The optoelectronic foil has a substrate 11 with a barrier layer 12 on which a conductive layer 13 comprising at least one oxide layer 131 and at least one metal layer 132 is deposited.

The substrate 11 of the optoelectronic foil 10 may be made of a variety of transparent substrate materials selected from the group consisting of plastics and/or plastics with nanocomposites of inorganic materials. For example, plastics for the substrate 11 may be provided in the form of at least one type of material selected from the group consisting of polyethylene terephthalate (PET), polyethylene naphthalene (PEN), polyethylene (PE), polypropylene (PP), polyethersulfone (PES), polyimide (PI), polystyrene (PS), ethylene/tetrafluoroethylene (ETFE) and polymers evaporated onto the surface from the group of poly-p-xylenes collectively referred to as parylene.

The barrier layer 12 of the foil 10 has a barrier function and prevents against moisture and oxygen penetration from the substrate 11 into the conductive layer 13, thus ensuring a significant reduction of degradation processes of the conductive layer that constitutes the optoelectronic element of the foil 10 and of the active layers of the device that can be deposited onto the optoelectronic foil 10.

The barrier layer 12 consists of at least one material selected from the group consisting of silicon oxides (SiOx), aluminium oxides (Al₂O₃, AlOₓN_{y}), titanium oxides (TiOₓ), silicon oxynitrides SiON, silicon nitrides (Si₃N₄, SiNₓ), organic silicon compounds (SiCₓH_{y}), zirconium oxide (ZrO₂), hafnium oxide (HfO₂), chromium oxides (CrO, Cr₂O₃, CrO₂, CrO₃, CrO₅) and parylene. In certain embodiments, the barrier layer may consist of at least two different materials selected from the group consisting of silicon oxides (SiOₓ), aluminium oxides (Al₂O₃, AlOₓN_{y}), titanium oxides (TiOₓ), silicon oxynitride SiON, silicon nitrides (Si₃N₄, SiNₓ), organic silicon compounds (SiCₓH_{y}), zirconium oxide (ZrO₂), hafnium oxide (HfO₂), chromium oxides (CrO, Cr₂O₃, CrO₂, CrO₃, CrO₅) and parylene.

In one embodiment, the barrier layer may take, for example, the form of a monolayer consisting of only one material, such as Al₂O₃. In another embodiment, the barrier layer may take the form of a monolayer comprising at least two different materials and may be made, for example, of Al₂O₃ doped with TiO₂. In yet another embodiment, the barrier layer 12 may consist of at least two different materials, and it may take the form of a multi-layer comprising, within the barrier layer 12, at least two sub-layers stacked one on the other, wherein each sub-layer may be made of different material or materials. For example, the barrier layer may have two sublayers, where one sublayer is made of Al₂O₃, and the other sublayer is made of TiO₂. Each sublayer within the barrier layer 12 may be of the same or different thickness, in some embodiments in the range between 5 and 500 nm, regardless of the thickness of another sublayer.

In certain embodiments, the barrier layer 12 comprises two sublayers, each made of a different material, selected from the group of materials listed above. The barrier layer 12 may have a total thickness which in certain embodiments is in the range between 5 and 1000 nm.

The conductive layer 13 is an optoelectronic active layer of the foil with conductive properties. The conductive layer 13 comprises at least one oxide layer 131, 133 and at least one metal layer 132 stacked one on the other.

Moreover, as shown in FIG. 1, the conductive layer may comprise at least two oxide layers 131 and 133, or more than two oxide layers, separated by metal layers 132 to form a sandwich architecture. All layers 131, 132, 133 are stacked in the conductive layer 13 one on the other, substantially in parallel.

In each embodiment of the conductive layer 13, for example comprising one or comprising more than one, for example two oxide layers 131, 133, the oxide layer 131, 133 is made of at least one oxide selected from the group consisting of: ZnO, AZO (aluminium zinc oxide), SnO₂, IZO (indium zinc oxide), FTO (fluorine tin oxide), ZTO (tin zinc oxide), ITO (tin indium oxide), GZO (zinc gallium oxide), GIO (indium gallium oxide), In₂O₃, Sb:SnO₂, IO:H (hydrogen indium oxide), CdO, Zn₂SnO₄, ZnSnO₃, Zn₂In₂O₅, NiOₓ, NiOₓ:Li, TiOₓ, ZnS, ZnSe, Te₂O₃, MoOₓ, V₂O₅ and WO₃. In each embodiment of the conductive layer 13 of the optoelectronic foil 10, the oxide layer 131, 133 may have a thickness in the range between 15 and 150 nm.

In one embodiment, the oxide layer 131, 133 may take the form of a monolayer and consist of one type of oxide, from the group of oxides listed above, for example ZnO. In another embodiment, the oxide layer may take the form of a monolayer and consist of more than one material, for example the oxide layer 131, 133, in the form of a monolayer may be made of ZnO doped with Al. In yet another embodiment, the oxide layer 131, 133 may consist of at least two different oxides and may take the form of a multilayer comprising, within one oxide layer 131, 133, at least two sublayers, wherein each sublayer is made of a different oxide material comprising at least one oxide. For example, the oxide layer 131, 133 may consist of two sublayers stacked one on the other within one oxide layer 131, 133, wherein one sublayer is made of ZnO and the other sublayer is made of AZO or IZTO doped with Al.

Depending on the intended use and the required parameters, the optoelectronic foil may comprise at least two oxide layers 131, 133, wherein one oxide layer takes the form of a monolayer and another oxide layer takes the form of a multilayer comprising at least two sublayers made of different oxide materials. Moreover, in each embodiment of the conductive layer 13 comprising one or more than one oxide layers, the metal layer 132 is made of at least one metal selected from the group consisting of: Al, Ti, Ni, Cr, Au, Mg, Ta, Ge, Ag, Cu, Zr, Pt and W. For each embodiment of the conductive layer 13 of the optoelectronic foil 10, the metal layer 132 may have a thickness in the range between 2 and 20 nm.

Depending on the target utility parameters of the optoelectronic foil, the foil 10 may have only one oxide layer 131, 133 being a multilayer or a monolayer, and only one metal layer 132 within the conductive layer 13. Furthermore, in another embodiment, the conductive layer 13 may comprise, as schematically shown in FIG. 1, two oxide layers 131, 133, each of which may be a multi- or monolayer, and one metal layer 132 separating the two oxide layers. In another embodiment, the conductive layer 13 may have three oxide layers and two metal layers stacked within the conductive layer one alternately on the other, so that each of the metal layers separates the two adjacent oxide layers. In yet another embodiment, the conductive layer may have n oxide layers 131, 133, each of which may be a multi- or monolayer, and n−1 metal layers stacked one on the other, so that each metal layer 132 separates two adjacent oxide layers 132, 133 forming a sandwich structure, where n is any number selected from the set of natural numbers. For example, n may be 2, 3, 4, 5, 6 or 7. For example, n may be up to 33, or n may be more than 33.

FIG. 2 schematically shows a manufacturing method of the optoelectronic foil.

A substrate material 11 is prepared in order to produce the optoelectronic foil in step 21. The preparation process involves thorough cleaning and activation of the selected substrate surface. The cleaning and activation process of step 21 is implemented using at least one technique selected from the group consisting of plasma treatment, corona discharge treatment, carbon dioxide treatment, cleaning with solvents such as acetone, isopropanol, water, or mixtures of acetone and water or a mixture of isopropanol and water, as well as surface treatment with ultraviolet (UV) radiation and ozone.

Then, in step 22, a barrier layer 12 is deposited onto the cleaned and activated surface of the substrate 11.

Depending on the structure of the barrier layer 12, step 22 may include one or more steps. For example, in order to form a barrier layer having a monolayer structure and made of at least one type of material, for example Al₂O₃, or Al₂O₃ doped with TiO₂, in step 22 the barrier layer may be deposited in one step. However, in order to form a barrier layer with a multilayer structure comprising at least two sublayers made of different materials, the deposition step 22 may comprise several sub-steps, each involving depositing one sublayer onto the barrier layer 12. For example, to form a barrier layer comprising two sublayers, the deposition in step 22 is implemented so that a sublayer of one material is deposited in the first step, and then a sublayer of another material selected from the material group for the barrier layer 12 listed above is deposited. The processes of depositing the barrier layer 12 having both the structure of a multilayer and monolayer may be implemented using at least one known deposition technique selected from the group consisting of: atomic layer deposition (ALD) technique, magnetron sputtering technique, electron-beam sputtering technique and thermal evaporation technique.

Then, in step 23, a conductive layer 13 is deposited onto the barrier layer having a multi- or monolayer structure, wherein each of the sublayers of the conductive layer 13, that is at least one oxide layer 131, 132 and at least one metal layer 132, is deposited onto the barrier layer 12 individually, in order to obtain the appropriate functionality and architecture of the conductive layer 13, e.g. a sandwich architecture. Each of the sublayers 131, 132, 133 of the conductive layer can be deposited using various deposition methods also known from the art, selected from the group consisting of: atomic layer deposition (ALD) technique, magnetron sputtering, electron-beam sputtering technique and thermal evaporation technique.

For example, the conductive layer 13 having the architecture, as shown in FIG. 1, comprising two oxide layers 131, 133 and a metal layer 132 between the oxide layers, is deposited in step 23 so that in the first step, the first oxide layer 131 is deposited directly onto the surface of the barrier layer 12, then a metal layer 132 is deposited onto the first oxide layer, and then a second oxide layer 133 is deposited onto the metal layer 132. Each of the sub-layers 131, 132, 133 may be deposited using the same or different deposition techniques.

Furthermore, depending on the target structure of the oxide layers 131, 133, each of which may take the form of a monolayer or a multilayer, the oxide layer 131, 133 may be deposited in step 23 in single step or several steps, each of which may be implemented using one technique as well as different deposition techniques. For example, for an oxide layer 131, 132 having a monolayer structure made of an oxide material containing one type of oxide, for example: Al₂O₃, or an oxide material containing two types of oxides, for example Al₂O₃ doped with TiO₂, the oxide layer 131, 133 may be deposited in single step 23. Now, in order to form the oxide layer 131, 133 having a multilayer structure consisting of at least two sublayers stacked one on the other, the oxide layer may be deposited in several steps in step 23, each step including depositing one sublayer within the oxide layer 131, 133.

The optoelectronic foil obtained combines barrier properties and an efficient conductive layer 13, which in certain embodiments has the architecture of an electrode, depending on the materials used as the materials for oxide and metal layers 131, 132, 133, respectively. In each embodiment of the foil 10, the conductive layer 13 is integrated with an flexible substrate 11, 12 having barrier properties.

The barrier layer of the optoelectronic foil has water vapor permeability rates (WVTR) ranging between 10⁻³ and 10⁻⁶ g/m² per day and has stable barrier properties, including high hydrophobicity and UV radiation resistance, which improves the lifespan of the conductive layer of the foil according to the invention.

Moreover, the optoelectronic foil is flexible and is characterised by relatively high transparency, while the conductive layer of the foil has good conductivity and is an alternative to the single, thicker conductive ITO (indium tin oxide) layer known in the prior art that is relatively brittle, has limited conductivity and is expensive.

### Example 1

The optoelectronic foil according to one embodiment of the invention is schematically shown as a cross-section in FIG. 1. The optoelectronic foil comprises a substrate 11, which in this embodiment is made of a plastic, namely polyethylene terephthalate (PET). The top surface of substrate 11 was cleaned and activated using oxygen plasma treatment. Then, a single barrier layer 12 made of AlOₓ with a thickness of 300 nm, which is an amorphous layer, was deposited onto the top surface of substrate 11 thus prepared in the reactive magnetron sputtering process. Next, a conductive layer 13 was deposited onto the barrier layer 12 in the reactive magnetron sputtering process, comprising the first oxide layer 131 made of ITO with a thickness of 20 nm, a metal layer 132 made of Ag with a thickness of 9 nm and a second oxide layer 133 made of ITO with a thickness of 20 nm. The optoelectronic foil thus obtained was subjected to tests involving a measurement of surface resistance by means of a four-point probe, a WVTR permeability measurement by means of a calcium test (measurement conditions RH=40%, T=25° C.) and measurement of light transmission in the visible spectrum using a UV-Vis spectrophotometer. The tests conducted yielded a surface resistance of the conductive layer 13 of 12 Ω/sq, a WVTR permeability rate of 10⁻³ g/m² per day and light transmission in the visible spectrum in the range of 70-78%.

The use of a three-layer electrode structure (conductive layer 13), where the two oxide layers 131, 133 are separated by a thin metal layer 132, provided high flexibility to the conductive layer 13 (due to the presence of the metal layer 12), and, as a result, to the entire optoelectronic foil, together with high conductivity are ensured, as demonstrated in the tests described above.

### Example 2

The optoelectronic foil according to another embodiment of the invention is schematically shown as a cross-section in FIG. 3. The optoelectronic foil comprises a substrate 11, which in this embodiment is made of a plastic, namely polyethylene terephthalate (PET). The top surface of substrate 11 was cleaned and activated using oxygen plasma treatment. Then, a barrier layer 12 in the form of an AlOₓ layer 121 with a thickness of 100 nm and a TiOx layer 122 with a thickness of 150 nm, which constitute amorphous layers, were deposited onto the top surface of substrate 11 thus prepared in the reactive magnetron sputtering process. Next, a conductive layer 13 was deposited onto the barrier layer 12 in the reactive magnetron sputtering process, containing the first oxide layer 131 made of ITO with a thickness of 20 nm, a metal layer 132 made of Ag with a thickness of 9 nm and a second oxide layer 133 made of ITO with a thickness of 20 nm. The optoelectronic foil thus obtained was subjected to tests involving a measurement of surface resistance by means of a four-point probe, a WVTR permeability measurement by means of a calcium test (measurement conditions RH=40%, T=25° C.) and measurement of light transmission in the visible spectrum using a UV-Vis spectrophotometer. The tests conducted yielded a surface resistance of the conductive layer 13 of 12 Ω/sq, a WVTR permeability rate of less than 5*10⁻⁴ g/m² per day and light transmission in the visible spectrum in the range of 67-80%.

While the invention has been described with respect to a limited number of embodiments, it will be appreciated that many variations, modifications and other applications of the invention may be made. Therefore, the claimed invention as recited in the claims that follow is not limited to the embodiments described herein.

What is claimed is:

1. An optoelectronic foil comprising a substrate and a conductive layer comprising at least one metal layer, wherein:
between the conductive layer and the substrate, the foil comprises a barrier layer comprising at least one material selected from the group consisting of silicon oxides (SiOₓ), aluminium oxides (Al₂O₃, AlOₓN_{y}), titanium oxides (TiOₓ), silicon oxynitrides SiON, silicon nitrides (Si₃N₄, SiN_{g}), organic silicon compounds (SiCₓH_{y}), zirconium oxide (Zr02), hafnium oxide (HfO₂), chromium oxides (CrO, Cr₂O₃, CrO₂, CrO₃, CrO₅) and parylene,
wherein the conductive layer further comprises at least two adjacent oxide layers, with the metal layer being a single layer of metal arranged between two adjacent oxide layers of the at least two adjacent oxide layers,
wherein each oxide layer of the at least two adjacent oxide layers is made of at least one oxide selected from the group consisting of: ZnO, AZO (aluminium zinc oxide), SnO₂, IZO (indium zinc oxide), FTO (fluorine tin oxide), ZTO (tin zinc oxide), ITO (tin indium oxide), GZO (zinc gallium oxide), GIO (indium gallium oxide), In₂O₃, Sb:SnO₂, IO:H (hydrogen indium oxide), CdO, Zn₂SnO₄, ZnSnO₃, Zn₂In2O₅, NiOₓ, NiOₓ:Li, TiOx, ZnS, ZnSe, Te₂O₃, MoOₓ, V₂O₅ and WO₃,
and wherein at least one of the oxide layers of the at least two adjacent oxide layers is:
either a monolayer structure
or a multi-layer structure consisting of at least two sublayers stacked one on the other within the oxide layer and wherein one of the sublayers is made of a different material than another sublayer.

2. The optoelectronic foil according to claim 1, wherein the barrier layer is a monolayer structure.

3. The optoelectronic foil according to claim 1, wherein the barrier layer is a multi-layer structure consisting of at least two sublayers stacked one on the other within the barrier layer and wherein one of the sublayers is made of a different material than another sublayer.

4. The optoelectronic foil according to claim 1, wherein the substrate is made of at least one plastic selected from the group consisting of: polyethylene terephthalate (PET), polyethylene naphthalene (PEN), polyethylene (PE), polypropylene (PP), polyethersulfone (PES), polyimide (PI), polystyrene (PS), ethylene/tetrafluoroethylene (ETFE) and parylene.

5. The optoelectronic foil according to claim 4, wherein the substrate is doped with inorganic nanocomposites.

6. The optoelectronic foil according to claim 1, wherein the metal layer is made of a material selected from the group consisting of: Al, Ti, Ni, Cr, Au, Mg, Ta, Ge, Ag, Cu, Zr, Pt and W.

7. The optoelectronic foil according to claim 1, wherein the conductive layer, comprises n oxide layers and n−1 metal layers arranged alternately between adjacent oxide layers.

8. A method for manufacturing an optoelectronic foil comprising:
cleaning and activating a selected surface of the substrate onto which a barrier layer is to be deposited,
forming the barrier layer on said cleaned and activated substrate,
and, after forming the barrier layer, forming a conductive layer comprises depositing at least one metal layer
wherein forming the barrier layer comprises depositing of at least one material selected from the group consisting of silicon oxides (SiOₓ), aluminium oxides (Al₂O₃, AlOₓN_{y}), titanium oxides (TiOₓ), silicon oxynitrides SiON, silicon nitrides (Si₃N₄, SiNₓ), organic silicon compounds (SiCₓH_{y}), zirconium oxide (ZrO₂), hafnium oxide (HfO₂), chromium oxides (CrO, Cr₂O₃, CrO₂, CrO₃, CrO₅) and parylene,
wherein forming the conductive layer further comprises depositing of at least two adjacent metal oxide layers each comprising at least one oxide selected from the group consisting of: ZnO, AZO (aluminum zinc oxide), SnO₂, IZO (indium zinc oxide), FTO (fluorine tin oxide), ZTO (tin zinc oxide), ITO (tin indium oxide), GZO (zinc gallium oxide), GIO (indium gallium oxide), In₂O₃, Sb:SnO₂, IO:H (hydrogen indium oxide), CdO, Zn₂SnO₄, ZnSnO₃, Zn₂In₂O₅, NiOₓ, NiOₓ:Li, TiOₓ, ZnS, ZnSe, Te₂O₃, MoOₓ, V₂O₅ and WO₃, and wherein depositing the metal layer comprises depositing a single layer of metal selected from the group consisting of: Al, Ti, Ni, Cr, Au, Mg, Ta, Ge, Ag, Cu, Zr, Pt and W,
wherein forming the conductive layer comprises forming on the barrier layer consecutively: a first oxide layer, a metal layer and a second oxide layer.

9. The method according to claim 8, wherein the barrier layer is formed by depositing one layer of material onto the substrate to form a barrier layer having a monolayer structure.

10. The method according to claim 8, wherein the barrier layer is formed by depositing at least two sublayers of different material onto the substrate to form the barrier layer having a multi-layer structure.

11. The method according to claim 8, wherein the conductive layer is formed so that on the barrier layer there are individually formed one on another, with an alternating arrangement of oxide layers and metal layers, n oxide layers and n−1 metal layers, wherein n is a natural number.

12. The method according to claim 8, wherein at least one oxide layer of the at least two adjacent metal oxide layers is formed by depositing one layer of oxide material to form an oxide layer having a monolayer structure.

13. The method according to claim 8, wherein at least one oxide layer of the at least two adjacent metal oxide layers is formed by depositing at least two oxide sublayers of different material to form an oxide layer having a multi-layer structure.

14. The method according to claim 8, wherein the substrate is cleaned and activated using at least one technique selected from the group consisting of: plasma treatment, corona discharge treatment, carbon dioxide treatment, ultraviolet radiation and ozone treatment, and cleaning with solvents selected from the group consisting of acetone, isopropanol, water, mixture of acetone and water and mixture of isopropanol and water.

15. The method according to claim 8, wherein the barrier layer and the conductive layer are independently deposited onto the substrate using at least one technique selected from the group consisting of atomic layer deposition (ALD), magnetron sputtering, electron-beam sputtering technique and thermal evaporation technique.
